(19) United States
(12) Patent Application Publication
(10) Pub. No.: US 2011/0155045 A1
(43) Pub. Date: Jun. 30, 2011

(54) Controlling the Temperature Profile in a Sheet Wafer

(75) Inventors: Kaitlin Olsen, Arlington, MA (US); Weidong Huang, Bolton, MA (US); Christine Richardson, Northborough, MA (US)

(73) Assignee: EVERGREEN SOLAR, INC., Marlborough, MA (US)

(21) Appl. No.: 13/015,258

(22) Filed: Jan. 27, 2011

Related U.S. Application Data
(63) Continuation-in-part of application No. 12/542,131, filed on Aug. 17, 2009.
Application No. 12/542,131 is a continuation-in-part of application No. 12/138,799, filed on Jun. 13, 2008.
Application No. 12/138,799 is a continuation-in-part of application No. 12/138,791, filed on Jun. 13, 2008.
(60) Provisional application No. 61/089,603, filed on Aug. 18, 2008.
(60) Provisional application No. 60/944,017, filed on Jun. 14, 2007.
(60) Provisional application No. 60/944,017, filed on Jun. 14, 2007.

(51) Int. Cl. C30B 15/20; C30B 15/10

(52) U.S. Cl. 117/24; 117/211; 425/270

(57) ABSTRACT

A sheet wafer growth system includes a crucible for containing molten material and an afterheater positioned above the crucible. The afterheater has an inner surface disposed toward the crucible. The system further includes one or more shields adjacent to the inner surface of the afterheater. The afterheater and the shield(s) are configured to allow a sheet wafer to pass adjacent to the shield(s). Each shield has two or more substantially different thermally conductive regions such that the two or more regions are configured to control the temperature profile of the growing sheet wafer.

### CROSS-REFERENCE TO RELATED APPLICATIONS

This patent application is a continuation-in-part of U.S. patent application Ser. No. 12/542,131 filed Aug. 17, 2009, which claims priority to U.S. Provisional Patent Application No. 61/089,603 filed Aug. 18, 2008, and which is a continuation-in-part application of U.S. patent application Ser. No. 12/138,799 filed Jun. 13, 2008 and U.S. patent application Ser. No. 12/138,791 filed Jun. 13, 2008, both applications of which claim priority to U.S. Provisional Patent Application No. 60/944,017 filed Jun. 14, 2007, the disclosures of which are incorporated by reference herein in their entirety. This patent application is also related to U.S. patent application entitled WIDE SHEET WAFER, which is being filed on the same date herewith and is incorporated by reference herein in its entirety.

### TECHNICAL FIELD

The invention generally relates to sheet wafers and, more particularly, the invention relates to controlling the temperature profile in the sheet wafer during the growth process.

### BACKGROUND ART

Solar cells may be formed from silicon wafers fabricated by a sheet wafer pulling technique. The sheet wafer pulling technique generally uses a crystal growth system that includes a specialized furnace surrounding a crucible containing molten silicon. The furnace generally includes a base insulation that surrounds the crucible, and insulation (known as an “afterheater”) positioned above the base insulation and near the growing sheet wafer.

During the growth process, two filaments are typically passed through the crucible so that molten silicon solidifies to its surface, thus forming a growing sheet wafer between the two filaments. Two or more sheet wafers may be formed at the same time by passing multiple sets of filaments through the crucible. The filaments with the sheet wafer attached are passed through the afterheater so that the sheet wafer may cool in a controlled environment. The sheet wafer is then removed from the furnace.

In general, prior art afterheaters known to the inventors provide only limited variability of the temperature profile in the growing sheet wafer. Consequently, as the growing sheet wafer cools, it may contain stresses that detrimentally affect its physical properties. These stresses undesirably can reduce the conversion efficiency of a solar cell ultimately made from such a sheet wafer.

### SUMMARY OF EMBODIMENTS

In accordance with one embodiment of the invention, a sheet wafer growth system includes a crucible for containing molten material and an afterheater positioned above the crucible. The afterheater has an inner surface disposed toward the crucible. The system further includes one or more shields adjacent to the inner surface of the afterheater. The afterheater and the shield(s) are configured to allow a sheet wafer to pass adjacent to the shield(s). Each shield has two or more substantially different thermally conductive regions such that the regions are configured to control the temperature profile of the growing sheet wafer.

In accordance with another embodiment of the invention, a method of growing a sheet wafer provides a crucible containing molten material and passes at least two filaments through the molten material to grow the sheet wafer. The method also provides an afterheater positioned above the crucible and adjacent to the sheet wafer on at least one side. The afterheater has a shield positioned between the sheet wafer and the afterheater. The shield has two or more substantially different thermally conductive regions such that the regions are configured to control the temperature profile of the growing sheet wafer.

In accordance with related embodiments, the shield(s) may be removably connected to a portion of the inner surface of the afterheater. The system or method may further include a housing that surrounds the crucible and the afterheater, and the shield(s) may be coupled to a portion of the housing. The system or method may further include a base insulation that surrounds the crucible on at least two sides, and the shield(s) may be coupled to a portion of the base insulation and are positioned between the base insulation and the crucible. The shield(s) may include one or more sheets and a rib on at least one side of each sheet. The shield(s) may include quartz, silicon carbide and/or aluminum oxide. The ribs may include aluminum oxide, graphite and/or a carbon fiber insulation material. The crucible may have at least two filament holes that define a vertically extending plane along a sheet wafer growth direction, and the rib(s) may be vertically aligned with an edge of the plane. The rib(s) may have various configurations. For example, a rib may have a continuously varying width, or may have one portion with a continuously varying width and another portion with a substantially constant width. Alternatively, or in addition, a rib may have two or more substantially constant widths, which may be arranged in an alternating pattern. One sheet may be formed from a material having one density and one rib may be formed from the same material having a second, substantially different density. Alternatively, or in addition, the sheet and/or the rib may be formed from a material having two or more densities within the material.

### BRIEF DESCRIPTION OF THE DRAWINGS

The foregoing and advantages of the invention will be appreciated more fully from the following further description thereof with reference to the accompanying drawings wherein:

FIG. 1 schematically shows a perspective view of a sheet wafer growth system according to various embodiments of the present invention;

FIG. 2 schematically shows a partially cut away view of the sheet wafer growth system of FIG. 1 with part of the housing removed;

FIG. 3 schematically shows a cross-sectional view of a sheet wafer growth system having a shield adjacent to an afterheater and to a base insulation according to various embodiments of the present invention;

FIG. 4 schematically shows a cross-sectional view of a sheet wafer growth system having a shield adjacent to an afterheater according to various embodiments of the present invention;

FIG. 5 schematically shows a partially cut away view of a sheet wafer growth system having a shield adjacent to an afterheater and coupled to a housing according to various embodiments of the present invention;

FIGS. 6A and 6B schematically show cross-sectional views of one portion of a sheet wafer growth system having a shield coupled to a base insulation according to various embodiments of the present invention;

FIG. 7A schematically shows a perspective view of one portion of an afterheater with a plurality of sheets according to various embodiments of the present invention;

FIG. 7B schematically shows a cross-sectional view of one portion of the afterheater shown in FIG. 7A according to various embodiments of the present invention;

FIGS. 8A-8C schematically show various sheet or rib configurations having different densities according to various embodiments of the present invention;

FIG. 9 schematically shows a sheet or rib configuration having two or more densities within the material according to various embodiments of the present invention;

FIGS. 10A-10C schematically show perspective views of one portion of an afterheater with a shield having various sheet and rib widths according to various embodiments of the present invention; and

FIGS. 11A-11D schematically show perspective views of various sheet configurations according to various embodiments of the present invention.

### DESCRIPTION OF ILLUSTRATIVE EMBODIMENTS

Various embodiments of the present invention provide a sheet wafer growth system and method of growing a sheet wafer that carefully controls the temperature profile in the sheet wafer during the growth and cooling process. This is accomplished by providing a shield adjacent to the growing sheet wafer that has two or more regions with different thermal conductivities positioned at designated areas in order to reduce the stresses within the growing ribbon crystal. Details of illustrative embodiments are discussed below.

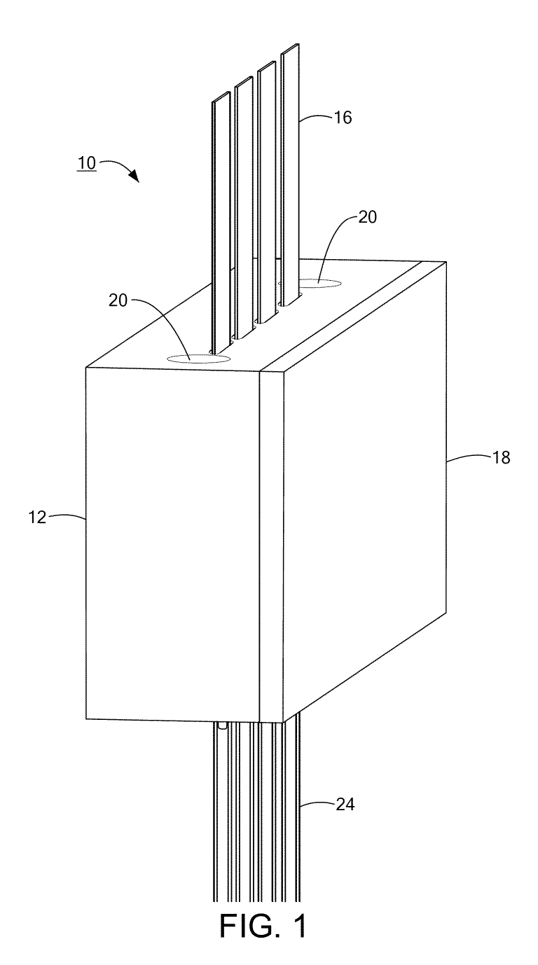

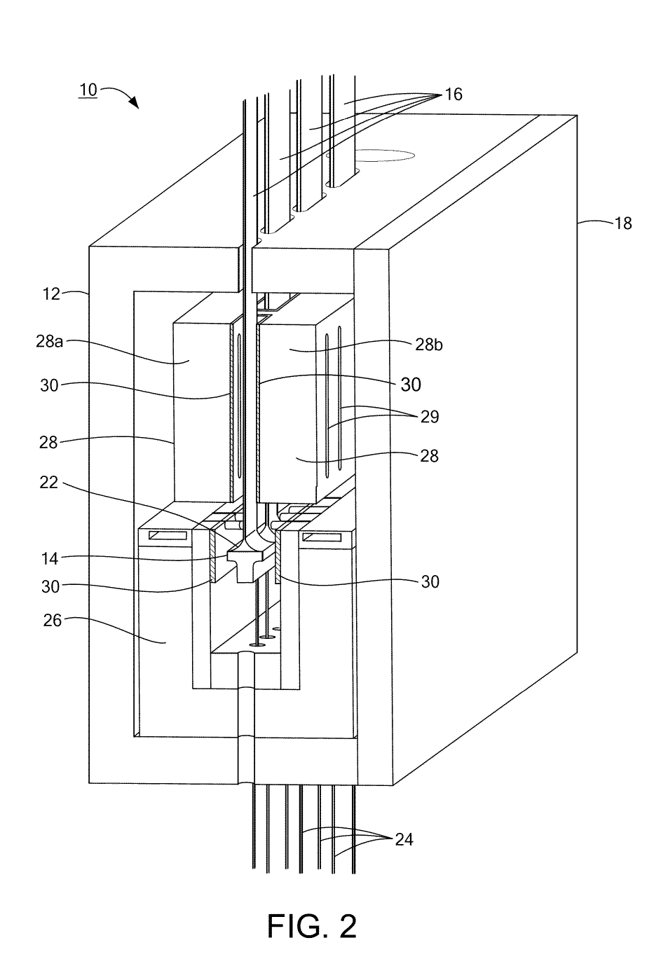

FIG. 1 schematically shows a sheet wafer growth system 10 according to various embodiments of the present invention. The growth system 10 may include a housing 12 forming an enclosed or sealed interior. The interior may be substantially free of oxygen (e.g., to prevent combustion) and may include one or more gases, such as argon or other inert gas, that may be provided from an external gas source. The interior includes a crucible 14 (as shown in FIGS. 2-6B) and other components for substantially simultaneously growing one or more silicon sheet wafers 16. Although FIG. 1 shows four sheet wafers, the growth system 10 may substantially simultaneously grow fewer or more of the sheet wafers. For example, the growth system 10 may grow two wider sheet wafers than that shown in FIG. 1. The sheet wafers 16 may be formed from single crystal silicon, multicrystalline silicon, or polycrystalline silicon. The housing 12 may include a door 18 to allow inspection of the interior and its components and one or more optional viewing windows 20. The housing 12 may also provides a means for directing feedstock material (not shown) into the interior of the housing 12 to the crucible 14 to be melted. It should be noted that discussion of the silicon sheet wafers 16 is illustrative and not intended to limit all embodiments of the invention. For example, the sheet wafers 16 may be formed from other materials, e.g., other metals or alloys.

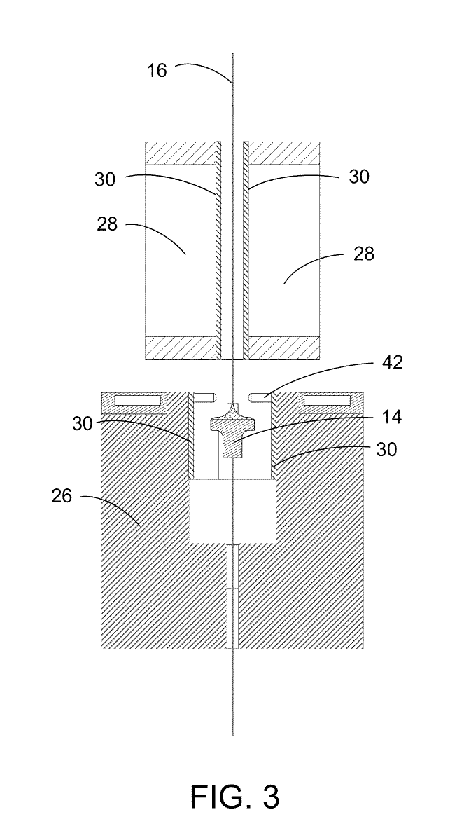

FIG. 2 schematically shows a partially cut away view of a growth system 10 with part of the housing 12 removed and FIG. 3 schematically shows a cross-sectional view of a growth system with the housing 12 removed. As shown, the growth system 10 includes a crucible 14 for containing molten material 22 in the interior of the housing 12. In one embodiment, the crucible 14 may have a substantially flat top surface that may support or contain the molten material 22. The crucible 14 may include filament holes (not shown) that allow one or more filaments 24 to pass through the crucible 14. As the filaments 24 pass through the crucible 14, molten silicon solidifies to its surface, thus forming the growing sheet wafer 16 between two filaments 24. The crucible 14 may have an elongated shape with a region for growing sheet wafers 16 in a side-by-side arrangement along its length.

The growth system 10 may also include insulation that is configured based upon the thermal requirements of the regions in the housing 12, e.g., the region containing the molten material 22 and the region containing the resulting growing sheet wafer 16. As such, the insulation may include a base insulation 26 that forms an area containing the crucible 14 and the molten material 22, and an afterheater 28 positioned above the base insulation 26 (from the perspective of the drawings). The afterheater 28 may be supported by the base insulation 26, e.g., by posts (not shown). In addition, or alternatively, the afterheater 28 may be attached or secured to a top portion of the housing 12 (not shown). In some embodiments, the afterheater 28 has two portions (28a, 28b) which are positioned on either side of the growing sheet wafers 16. The two portions 28a, 28b form one or more channels between the portions through which the sheet wafer 16 grows. Alternatively, the afterheater 28 may also be positioned on only one side of the growing sheet wafers 16. The afterheater 28 provides a controlled thermal environment that allows the growing sheet wafer 16 to cool as it rises from the crucible 14. In some embodiments, the afterheater 28 may have one or more additional openings or slots 29 within the afterheater 28 for controllably venting heat from the growing sheet wafers 16 as it passes through the inner surface of the afterheater 28.

In some embodiments, the growth system 10 may also include a gas cooling system that may supply gas from an external gas source (not shown) to gas cooling jets 42 through a gas cooling manifold 44. The gas cooling system may provide gas to further cool the growing sheet wafer 16. For example, as shown in FIGS. 2-6B, the gas cooling jets 42 may face toward the growing sheet wafer 16 in the area above the crucible 14.

The growth system 10 may also include one or more shields 30 that each have two or more regions with substantially different thermal conductivities in order to control the temperature profile in the growing sheet wafers 16. Various configurations of the shields will be discussed in more detail below. During the growth and cooling process, the growing sheet wafers 16 may have stresses that develop within it due to temperature variations within the sheet wafer 16 as various areas cool faster or slower than other areas. In addition, stresses may develop between the sheet wafer 16 and the filaments 24 due to the differences between the coefficient of thermal expansion of these two materials. The shield 30 selectively cools certain areas of the growing sheet wafer 16 compared to others in order to control the temperature profile in the sheet wafer 16 as it cools, thus reducing the stresses in resulting sheet wafer 16.

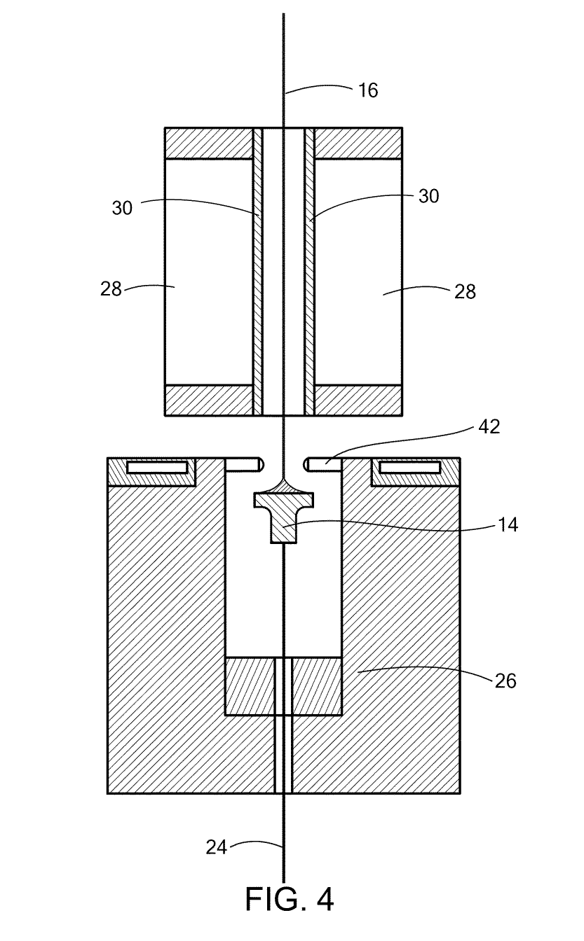

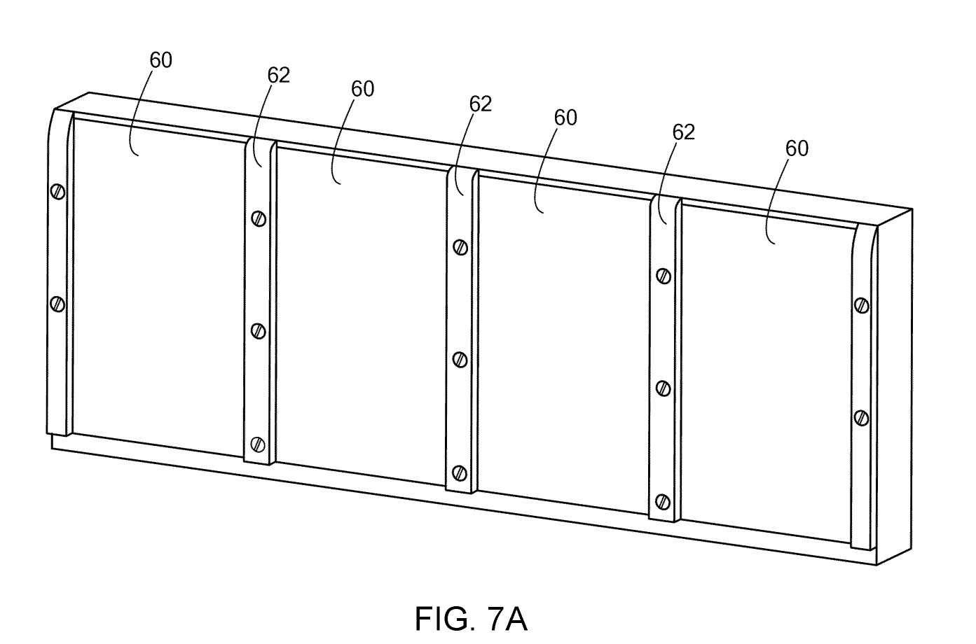

The shield 30 may be adjacent to at least a portion of the afterheater 28 positioned between the afterheater 28 and the sheet wafers 16. Preferably, the shield 30 is adjacent to the afterheater 28 on either side of the sheet wafers 16. The shield 30 may be coupled to the inner surface of the afterheater 28, as shown in FIG. 4, or may be attached to the top of the afterheater 28 (not shown). Although FIG. 4 shows the shield 30 on the inner surface of the afterheater 28, the shield 30 may also be included on other surfaces of the afterheater 28, such as discussed below with respect to FIG. 7B.

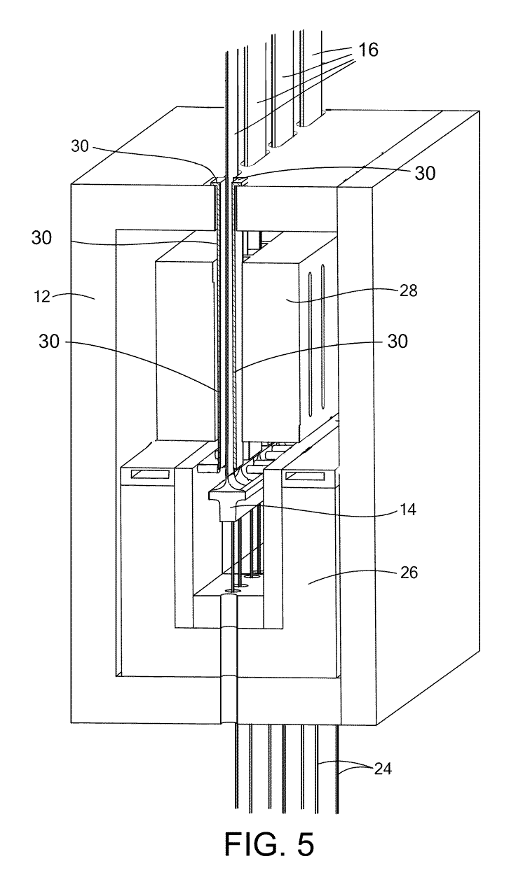

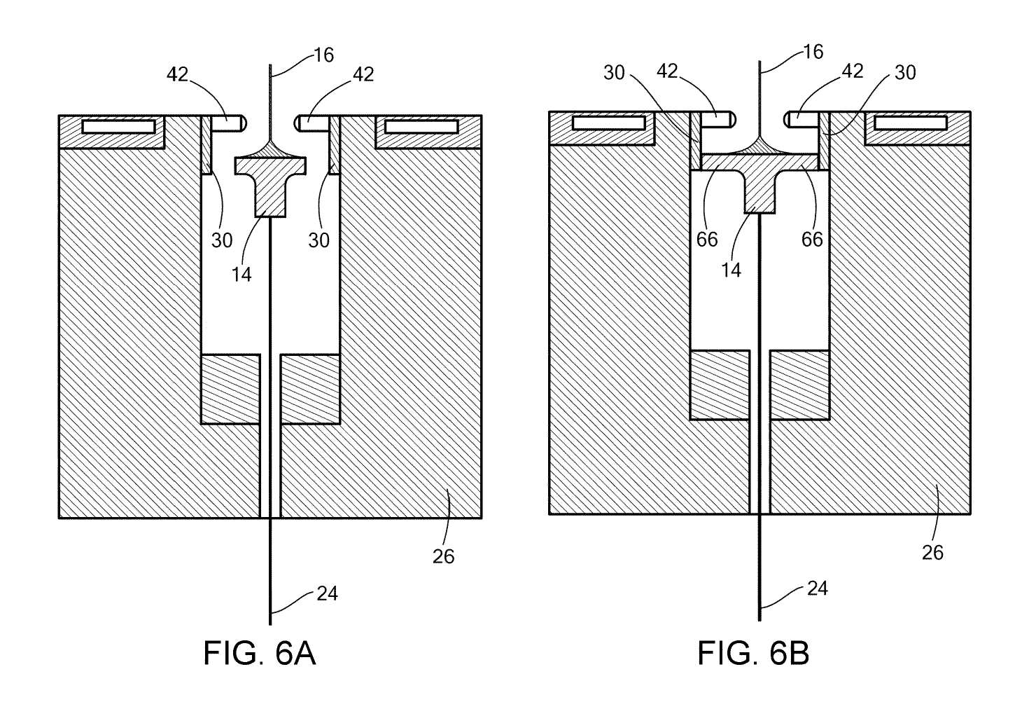

Alternatively, the shield 30 may be attached to the top of the housing 12 and positioned adjacent to the channel in the housing 12 that allows the sheet wafer to pass through it, such as shown in FIG. 5. In this embodiment, the shield may extend downward, ending somewhere above the crucible 14. Alternatively, or in addition, the shield 30 may be coupled to at least a portion of the base insulation 26 positioned between the base insulation 26 and the crucible 14. For example, FIGS. 6A and 6B schematically show a cross-sectional view of a bottom portion of a sheet wafer growth system 10 having a shield 30 coupled to the base insulation 26. Preferably, the shield 30 is coupled to the base insulation 26 on either side of the crucible 14 and ends somewhere below the top of the crucible 14 where the molten material 22 is contained. The shields 30 and the crucible 14 may have a space between them, such as shown in FIG. 6A. Alternatively, the upper section of the crucible 14 may include one or more baffles 66 that extend to the shields 30 on either side of the crucible 14 so that the shields 30 and the crucible 14 adjoin one another. The baffles 66 may prevent contamination from the base insulation 26 from being incorporated into the growing sheet wafer 16 near the molten material 22.

The shield 30 may be provided along the length of the afterheater 28, such as shown in FIGS. 2-4. Alternatively, the shield 30 may extend beyond the bottom of the afterheater 28 and end somewhere above the crucible 14, such as shown in FIG. 5, so that the temperature profile in the sheet wafer 16 may be controlled during the majority of the cooling process. Similarly, the shield 30 may be provided in the upper portion of the base insulation 26, the top of which may be substantially coplanar with the top of the base insulation 26, such as shown in FIGS. 6A and 6B. Alternatively, the top of the shield 30 may extend above the top of the base insulation 26, not shown, and may extend somewhere between the base insulation 26 and the afterheater 28, or may adjoin the bottom of the afterheater 28.

Whether adjacent to the afterheater 28, adjacent to the base insulation 26, or both, the shields 30 may be removably coupled to the afterheater 28, the housing 12, and/or the base insulation 26 so that the shield 30 may be easily replaced or cleaned if it becomes contaminated over time during the growth process, e.g., molten silicon splashing on it or damaged it in some way. One or more shields 30 may be used for each sheet wafer 16 grown in the growth system 10 or one or more shields 30 may be used for all of the sheet wafers 16 grown in the growth system.

It is believed that contaminants may be carried to the sheet wafer surface from the insulation materials surrounding the growing sheet wafer 16 during a time when the sheet wafer 16 is more susceptible to incorporating these contaminants into the surface of the material, i.e., when the sheet wafer 16 is initially formed from the melt and beginning to cool. Thus, the shields 30 may also provide a protective barrier in the system, so as to reduce gas borne contaminants coming from the base insulation 26 and/or the afterheater 28 to minimize the impact of these contaminants during the growth process.

In order to protect the sheet wafers 16 from contaminants from the base insulation 26 and/or the afterheater 28, portions of the shield 30 may be formed from a very pure, high quality material that is able to withstand relatively high temperatures. For example, the shield material preferably operates in temperatures ranging from about 1000° C. to about 1500° C. The base insulation 26 and/or the afterheater 28 are typically formed from a low density, carbon insulation material such as carbon foam, carbon fiber or graphite foam materials. Thus, portions of the shield 30 may be formed from a variety of materials that have a higher purity than the typical insulation materials, although other portions of the shield 30 may be formed from the same or similar materials as the base insulation 26 and/or the afterheater 28. Preferably, one or more portions of the shield 30 are formed from a hard, dense material. For example, portions of the shield 30 may be formed of silicon carbide, quartz, graphite, aluminum oxide or a combination thereof. The shield 30 may be a layer, such as a cladding layer, formed on or coupled to the base insulation 26 and/or the afterheater 28. Alternatively, the shield 30 may be a coating formed on the base insulation 26 and/or the afterheater 28 or formed on a shield material, e.g., CVD silicon carbide coating graphite.

The shield 30 may be formed from a plurality of sheets or plates attached to the base insulation 26 and/or the afterheater 28 with one or more ribs. For example, FIGS. 7A and 7B schematically show a perspective view and cross-sectional view, respectively, of a shield 30 with a plurality of sheets or plates 60 coupled to the inner surface of an afterheater 28 with one or more ribs 62. In addition to the inner surface of the afterheater 28 and/or the base insulation 26, the shield 30 may also be included on other surfaces of the afterheater 28 or base insulation 26. For example, the shield 30 may substantially surround the afterheater 28, such as shown in FIG. 7B.

The sheets 60 and the ribs 62 may be positioned in the afterheater 28 and/or the base insulation 26 in such a way as to control the temperature gradients near the growing sheet wafer 16, potentially reducing the stresses within the resulting sheet wafer 16. The ribs 62 may be positioned at specified locations to control certain characteristics and qualities of the growing sheet wafers 16. For example, the crucible 14 may have a plurality of filament holes (not shown) for receiving two or more filaments 24. As the filaments 24 pass through the crucible 14, molten silicon solidifies to its surface, thus forming a growing sheet wafer 16 between the two filaments 24. Undesirably, there may be portions of the growing sheet wafer 16 that, absent some further cooling, may be thinner than intended (e.g., forming thin, fragile “neck regions”). Therefore, the ribs 62 may be positioned near those sections of the growing sheet wafer 16 to ensure appropriate cooling and thus, the desired thickness in the sheet wafer 16.

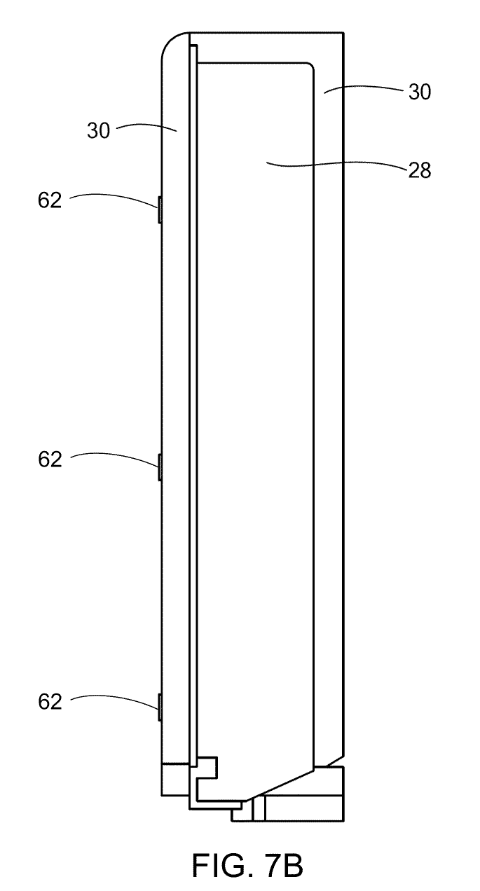

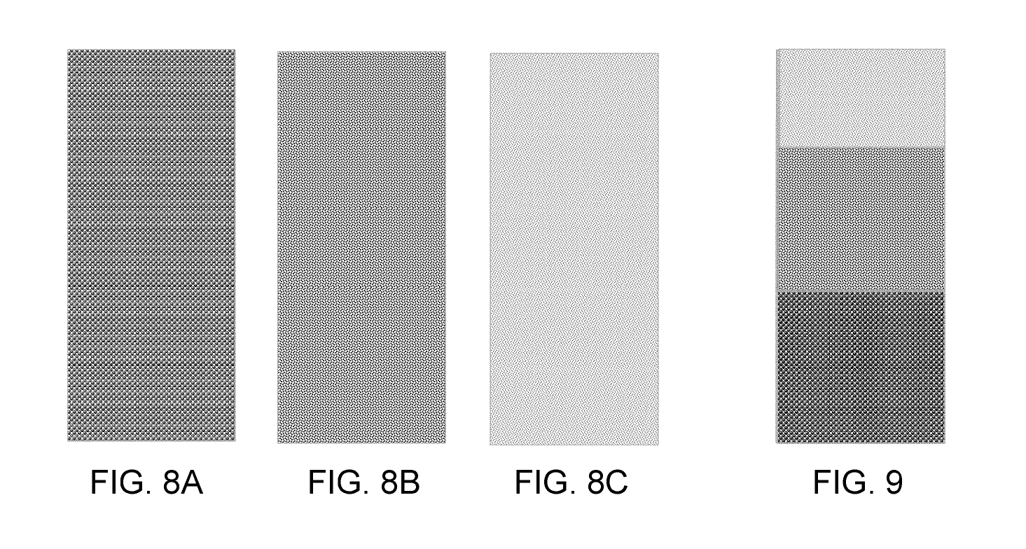

Accordingly, the sheets 60 and ribs 62 may be formed from a material that has substantially different thermal conductive properties from one another. For example, the ribs 62 may be formed from a material that has a higher conductive property than the sheets 60. For instance, the sheets 60 may be formed of silicon carbide, quartz, aluminum oxide and/or a low density, carbon fiber insulation material, such as Fiberform, and the ribs 62 may be formed of graphite and/or aluminum oxide. Alternatively, or in addition, the sheets 60 and ribs 62 may be formed from substantially the same type of material, but the density of the material may be different so that each has effectively different thermal conductive properties from one another. For example, FIGS. 8A-8C show sheets 60 and/or ribs 62 with different densities from one another. Alternatively, or in addition, the sheets 60 and/or ribs 62 may have two or more densities within the material, such as shown FIG. 9. This allows the configuration of the sheets 60 and/or ribs 62 to vary both in the horizontal direction, e.g., from side-to-side in the growing sheet wafer 16, and/or in the vertical direction, e.g., from top-to-bottom in the growing sheet wafer 16 from the perspective of the drawings.

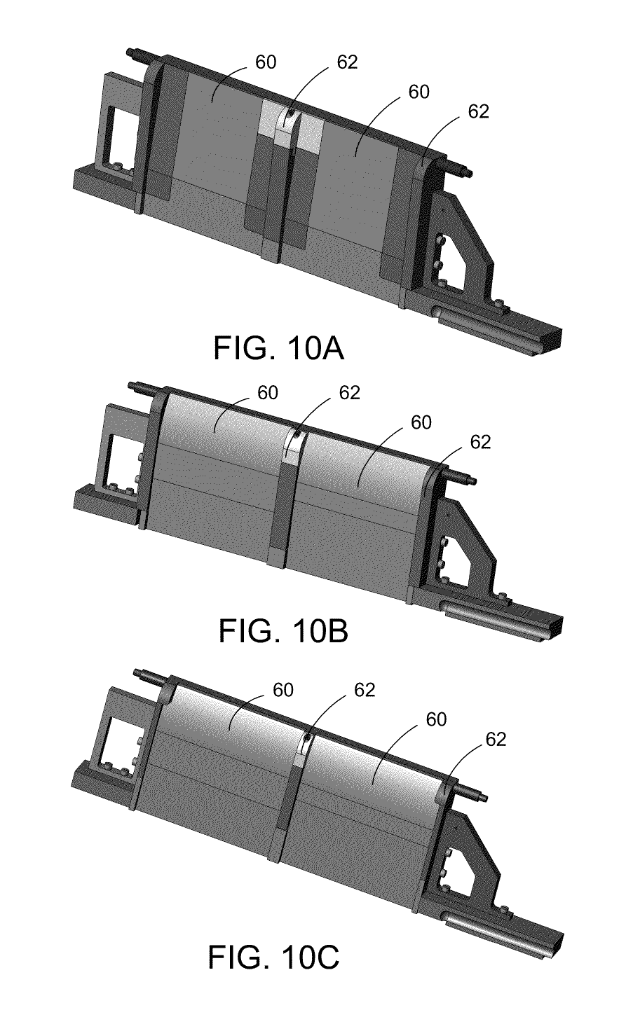

The configuration of the sheets 60 and ribs 62 may be varied depending on the desired characteristics and qualities of the growing sheet wafers 16. For example, as shown in FIG. 10A, the outer portions of the sheets 60 adjacent to the ribs 62 may be formed from materials having similar thermal conductive properties as the ribs 62, effectively enlarging the cooling areas in the sheet wafer 16. Alternatively, or in addition, a larger or smaller rib 62 may be used at the sides of the sheets 60 to effectively enlarge or reduce the cooling areas in the sheet wafer 16, such as shown in FIG. 10B and 10C. The size and shape of the sheets 60 and/or the ribs 62 may be readily changed to allow various cooling designs to be evaluated during development. Also, the sheet 60 and rib 62 configuration may be readily be changed to compensate for process variations, such as a material variation within the insulation material, so that a consistent cooling profile may be achieved.

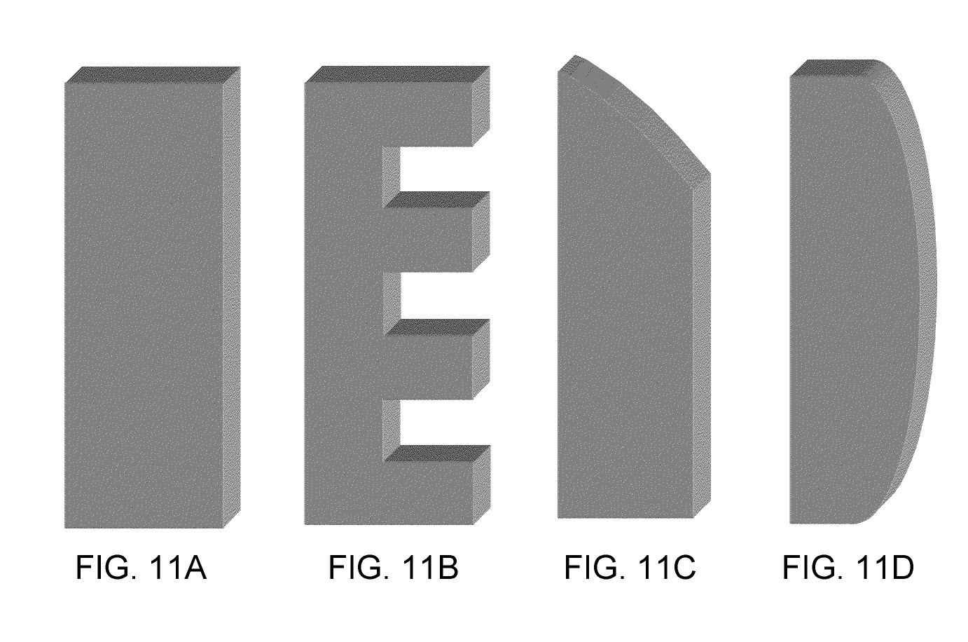

The shape of the ribs 62 may also have various configurations. For example, as shown in FIG. 11A, and previously in FIGS. 7A and 10A-10C, one or more of the ribs 62 may be in the form of rectangular strips that each have a substantially uniform width. Alternatively, or in addition, one or more of the ribs 62 may have two or more substantially constant widths, which may be arranged in an alternating pattern, such as shown in FIG. 11B. Alternatively, or in addition, one or more of the ribs 62 may have varying widths or portions with varying widths. For example, FIG. 11C shows a rib 62 with a continuously varying width at its upper portion and a substantially constant width at its lower portion, and FIG. 11C shows a rib 62 with a continuously varying width. The ribs 62 may also have different shapes either uniform or varying, e.g., oval shapes, irregular shapes, etc. The ribs 62 may be positioned adjacent to one another with each rib 62 extending substantially the length of the afterheater 28 in the vertical direction, as shown in FIGS. 10A-10C. Alternatively, the ribs 62 may include shorter sections that are vertically aligned on top of one another with little to no space between sections, or a designated amount of space between sections. The size and shape of the ribs 62 may be varied depending on the desired thickness of the sheet wafers 16. However, in general, the size and shape should not be too large because the sheet wafer 16 may become too thick at certain areas, and/or have undesirable internal strains or stresses. The size and shape of the ribs 62 thus should be carefully controlled to minimize such strains or stresses, and ensure appropriate sheet wafer thickness.

For example, two filament holes may be considered as forming a plane extending vertically upwardly through the system 10 along the sheet wafer growth direction. The sheet wafer 16 grows generally parallel to this plane. The ribs 62 may be positioned or aligned along the edge of this plane or the growing sheet wafer 16, or may be positioned anywhere along this vertically extending plane, thus reducing the temperature in that region of the system 10. Reducing the temperature in that region should have the effect of increasing the sheet wafer thickness in the corresponding area.

In order to vary the temperature profile in the growing sheet wafer 16, the shield 30 position may be also be moved closer to or further away from the sheet wafer 16 in order to adjust the amount of cooling in selected areas.

Although the above discussion discloses various exemplary embodiments of the invention, it should be apparent that those skilled in the art can make various modifications that will achieve some of the advantages of the invention without departing from the true scope of the invention.

What is claimed is:

1. A sheet wafer growth system comprising:
a crucible for containing molten material;
an afterheater positioned above the crucible, the afterheater having an inner surface disposed toward the crucible; and
at least one shield adjacent to the inner surface, wherein the afterheater and the at least one shield are configured to allow a sheet wafer to pass adjacent to the at least one shield, each shield having at least two regions with substantially different thermal conductivities from one another, the at least two regions configured to control the temperature profile of the sheet wafer.

2. The sheet wafer growth system of claim 1, wherein the at least one shield is removably connected to a portion of the inner surface of the afterheater.

3. The sheet wafer growth system of claim 1, further comprising:
a housing that surrounds the crucible and the afterheater, the housing configured to allow the sheet wafer to pass through a channel in the housing, wherein the at least one shield is coupled to a portion of the housing.

4. The sheet wafer growth system of claim 1, further comprising:
a base insulation that surrounds the crucible on at least two sides, wherein the at least one shield is coupled to a portion of the base insulation and is positioned between the base insulation and the crucible.

5. The sheet wafer growth system of claim 1, wherein the at least one shield comprises at least one sheet and at least one rib on at least one side of each sheet.

6. The sheet wafer growth system of claim 5, wherein the at least one sheet comprises quartz, silicon carbide, aluminum oxide, or a combination thereof.

7. The sheet wafer growth system of claim 5, wherein the at least one rib comprises aluminum oxide, graphite, a carbon fiber insulation material, or a combination thereof.

8. The sheet wafer growth system of claim 5, wherein the crucible has at least two filament holes that define a vertically extending plane along a sheet wafer growth direction, and the at least one rib is vertically aligned with an edge of the plane.

9. The sheet wafer growth system of claim 5, wherein the at least one rib has a continuously varying width.

10. The sheet wafer growth system of claim 5, wherein the at least one rib has one portion with a continuously varying width and another portion with a substantially constant width.

11. The sheet wafer growth system of claim 5, wherein the at least one rib has two or more widths in an alternating pattern.

12. The sheet wafer growth system of claim 5, wherein the at least one sheet is formed from a material having one density and the at least one rib is formed from the same material having a second, substantially different density.

13. The sheet wafer growth system of claim 5, wherein the at least one sheet, the at least one rib, or both, is formed from a material having a varying density in at least a portion of the material.

14. A method of growing a sheet wafer, the method comprising:
providing a crucible containing molten material;
passing at least two filaments through the molten material to grow the sheet wafer; and
providing an afterheater positioned above the crucible and adjacent to the sheet wafer on at least one side, the afterheater having a shield positioned between the sheet wafer and the afterheater, the shield having at least two regions with substantially different thermal conductivities from one another, the at least two regions configured to control the temperature profile of the sheet wafer.

15. The method of claim 14, wherein the shield is removably connected to a portion of the afterheater.

16. The method of claim 14, further comprising:
providing a base insulation that surrounds the crucible on at least two sides, wherein the shield is coupled to a portion of the base insulation and is positioned between the base insulation and the crucible.

17. The method of claim 14, further comprising:
providing a housing that surrounds the crucible and the afterheater, wherein the shield is coupled to a portion of the housing and is adjacent to a portion of the sheet wafer.

18. The method of claim 14, wherein one region comprises at least one sheet and the other region comprises at least one rib on at least one side of each sheet, the at least one sheet comprising quartz, silicon carbide, aluminum oxide, or a combination thereof.

19. The method of claim 14, wherein one region comprises at least one sheet and the other region comprises at least one rib on at least one side of each sheet, the at least one rib comprising aluminum oxide, graphite, a carbon fiber insulation material, or a combination thereof.

20. The method of claim 14, wherein one region comprises at least one sheet and the other region comprises at least one rib on at least one side of each sheet, wherein the at least one rib that is vertically aligned near an edge of the sheet wafer.

21. The method of claim 20, wherein the at least one rib that has a continuously varying width.

22. The method of claim 20, wherein the at least one rib has one portion with a continuously varying width and another portion with a substantially constant width.

23. The method of claim 20, wherein the at least one rib has two or more widths in an alternating pattern.

24. The method of claim 14, wherein one region is formed from a material having one density and the other region is formed from the same material having a second, substantially different density.

25. The method of claim 14, wherein one or both regions are formed from a material having a varying density in at least a portion of the material.
